(19) United States
(12) Patent Application Publication
(10) Pub. No.: US 2024/0402104 A1
(43) Pub. Date: Dec. 5, 2024

(54) MULTI-BEAM PARTICLE MICROSCOPE FOR REDUCING PARTICLE BEAM-INDUCED TRACES ON A SAMPLE

(71) Applicant: Carl Zeiss MultiSEM GmbH, Oberkochen (DE)

(72) Inventors: Gero Storeck, Aalen (DE); David Disterheft, Aalen (DE); Holger Kierey, Aalen (DE)

(21) Appl. No.: 18/801,091

(22) Filed: Aug. 12, 2024

Related U.S. Application Data
(63) Continuation of application No. PCT/EP2023/025061, filed on Feb. 10, 2023.

(30) Foreign Application Priority Data
Feb. 25, 2022 (DE) 10 2022 104 535.8

(51) Int. Cl. G01N 23/2251; H01J 37/09; H01J 37/10

(52) U.S. Cl. CPC G01N 23/2251; H01J 37/09; H01J 37/10

(57) ABSTRACT

A multi-beam particle microscope can reduce particle beam-induced traces on a sample at which a high voltage is present. The occurrence of additional residual gas in the sample chamber is reduced using a specific objective lens cable and/or a specific sample stage cable, which are specifically shielded.

### CROSS-REFERENCE TO RELATED APPLICATIONS

The present application is a continuation of, and claims benefit under 35 USC 120 to, international application No. PCT/EP2023/025061, filed Feb. 10, 2023, which claims benefit under 35 USC 119 of German Application No. 10 2022 104 535.8, filed Feb. 25, 2022. The entire disclosure of each of these applications is incorporated by reference herein.

### FIELD

The disclosure relates to a multi-beam particle microscope for reducing particle beam-induced traces on a sample.

### BACKGROUND

With the continuous development of ever smaller and ever more complex microstructures such as semiconductor components, it is desirable to further develop and optimize planar production techniques and inspection systems for producing and inspecting small dimensions of the microstructures. By way of example, the development and production of the semiconductor components generally involves monitoring of the design of test wafers, and the planar production techniques involve process optimization for a reliable production with a high throughput. Moreover, there have been recent demands for an analysis of semiconductor wafers for reverse engineering and for a customer-specific, individual configuration of semiconductor components. Therefore, it is desirable to provide an inspection mechanism which can be used with a high throughput for examining the microstructures on wafers with great accuracy.

Typical silicon wafers used in the production of semiconductor components have diameters of up to 300 mm. Each wafer is subdivided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case extends from a few μm to the critical dimensions (CD) of 5 nm, wherein the structure dimensions will become even smaller in the near future; in future, structure sizes or critical dimensions (CD) are expected to be less than 3 nm, for example 2 nm, or even less than 1 nm. In the case of the aforementioned small structure sizes, defects in the size of the critical dimensions are desirably identified quickly in a very large area. For several applications, the specification regarding the accuracy of a measurement provided by inspection equipment is even higher, for example by a factor of two or one order of magnitude. By way of example, a width of a semiconductor feature are measured with an accuracy of below 1 nm, for example 0.3 nm or even less, and a relative position of semiconductor structures are determined with an overlay accuracy of below 1 nm, for example 0.3 nm or even less.

The MSEM, a multi-beam scanning electron microscope, is a relatively new development in the field of charged particle systems (“charged particle microscopes”, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or grid. By way of example, 4 to 10,000 individual electron beams can be provided as primary radiation, with each individual electron beam being separated from an adjacent individual electron beam by a pitch of 1 to 200 micrometres. By way of example, an MSEM has approximately 100 separate individual electron beams (“beamlets”), which are arranged for example in a hexagonal grid, with the individual electron beams being separated by a pitch of approximately 10 μm. The plurality of charged individual particle beams (primary beams) are focused on a surface of a sample to be examined by way of a common objective lens. By way of example, the sample can be a semiconductor wafer which is secured to a wafer holder mounted on a movable stage. During the illumination of the wafer surface with the charged primary individual particle beams, interaction products, for example secondary electrons or backscattered electrons, emanate from the surface of the wafer. Their start points correspond to those locations on the sample on which the plurality of primary individual particle beams are focused in each case. The amount and the energy of the interaction products depend on the material composition and the topography of the wafer surface. The interaction products form a plurality of secondary individual particle beams (secondary beams), which are collected by the common objective lens and which are incident on a detector arranged in a detection plane as a result of a projection imaging system of the multi-beam inspection system. The detector comprises a plurality of detection regions, each of which comprises a plurality of detection pixels, and the detector captures an intensity distribution for each of the secondary individual particle beams. An image field of, for example, 100 μm×100 μm is obtained in the process.

A known multi-beam electron microscope can comprise a sequence of electrostatic and magnetic elements. At least some of the electrostatic and magnetic elements are settable in order to adapt the focus position and the stigmation of the plurality of charged individual particle beams. Such a multi-beam system with charged particles can moreover comprise at least one cross-over plane of the primary or the secondary charged individual particle beams. Moreover, such a system can comprise detection systems to make the adjustment easier. Such a multi-beam particle microscope can comprise at least one beam deflector (“deflection scanner”) for collective scanning of a region of the sample surface via the plurality of primary individual particle beams in order to obtain an image field of the sample surface. Further details regarding a multi-beam electron microscope and a method for operating same are described in the international patent application with the application number WO 2021239380 A1, the disclosure of which is fully incorporated by reference in the present patent application.

In order to be able to carry out a precision inspection of a sample or sample surface using a multi-beam scanning electron microscope, or more generally using a multi-beam particle microscope, it is desirable to work with very clean samples in a very clean environment under high vacuum. Contaminations or residual gases in the vacuum that can be taken up on a sample surface can lead to drastic changes in contrast during image generation using the multi-beam particle microscope, which can make an accurate analysis more difficult or even impossible. In this case, adsorption of particles on the sample surface can take place spontaneously or in a manner induced by the particle beam. In this case, a particle beam-induced contamination is normally caused by growth of carbon on the sample surface. A known and successful measure for preventing this contamination is the use of materials in the vacuum chamber which do not outgas or hardly outgas carbon.

US 2020/0373116 A1 discloses a multi-beam electron microscope which, in addition to secondary electrons, can detect backscattered electrons as well. For this purpose, a specific membrane is provided between the sample and the lower pole shoe of the objective lens.

US 2020/0243296 A1 discloses a multi-beam particle microscope having an objective lens comprising three pole shoes. In that case, an electrical insulation is provided between the pole shoes. A shielding electrode for reducing charging of the sample is additionally disclosed.

US 2007/0194230 A1 relates to the examination of a magnetic sample via SPLEEM.

### SUMMARY

Experiments conducted by the applicant have shown that even under high vacuum measures discussed above may not suffice to sufficiently reduce the particle beam-induced traces on a sample surface—at any rate not when at the same time the desired accuracy in inspection tasks via multi-beam particle microscopes is increasing further and further.

The disclosure seeks to improve existing multi-beam particle microscopes. The disclose seeks to provide a multi-beam particle microscope which enables particle beam-induced traces on a sample to be reduced further.

The disclosure is based on experiments conducted by the applicant regarding the occurrence of the described particle beam-induced contaminations or particle beam-induced traces on the sample surface. In this case, it has been found that there is a further source of contaminations, which had not been known previously in the context of multi-beam particle microscopes. Specifically, the contaminations can occur if a multi-beam particle microscope is employed in which a very high or (in the case of negatively charged particles such as electrons) a very low voltage is present at the objective lens and/or at the sample stage under vacuum. Whenever high electric fields occur within the vacuum chamber with the sample to be examined, contaminations increasingly arise in accordance with the applicant's results. An explanation for this is internal discharges or corona discharges within the vacuum chamber which occur in the vicinity of cables. This affects for example the objective lens cable and the sample stage cable, at which very high voltages are present in terms of absolute value relative to the grounded vacuum chamber. If a discharge occurs in the vacuum chamber, atoms or molecules or generally residual gases still present in the vacuum chamber can be ionized and accelerated. These ions then can strike for example the grounded wall of the vacuum chamber or the cables and eject material there (sputtering effect), for example from the material of the insulators that typically surround the cables. Overall, owing to the internal discharge or corona discharge, on account of sputtering effects, the amount of disturbing residual material or residual gas present in the vacuum chamber can thus be more than there would be in the absence of a corresponding discharge.

The disclosure makes use of these insights. As part of the disclosure, the occurrence of internal discharges or corona discharges in the vacuum chamber containing the sample can be reduced or completely prevented.

In accordance with a first aspect of the disclosure, the latter therefore relates to a multi-beam particle microscope for reducing particle beam-induced traces on a sample, comprising the following features: a multi-beam generator configured to produce a first field of a plurality of charged first individual particle beams; a first particle optical unit with a first particle optical beam path, configured to image the produced individual particle beams onto a sample surface in the object plane such that the first individual particle beams are incident on the sample surface at incidence locations, which form a second field; a detection system with a plurality of detection regions that form a third field; a second particle optical unit with a second particle optical beam path, configured to image second individual particle beams, which emanate from the incidence locations in the second field, onto the third field of the detection regions of the detection system; a magnetic and/or electrostatic objective lens, through which both the first and the second individual particle beams pass; a beam switch, which is arranged in the first particle optical beam path between the multi-beam generator and the objective lens and which is arranged in the second particle optical beam path between the objective lens and the detection system; a sample stage for holding and/or positioning a sample during a sample inspection; and a controller configured to control the multi-beam particle microscope, wherein the objective lens and the sample stage are arranged in a vacuum chamber, which is grounded; wherein a high voltage is able to be applied or is applied to the objective lens via an objective lens cable that is guided at least sectionally within the vacuum chamber; wherein a high voltage is able to be applied or is applied to the sample stage via a sample stage cable that is guided at least sectionally within the vacuum chamber; wherein the objective lens cable at least partly has a shield in the section guided in the vacuum chamber, such that electrostatic discharges between the objective lens cable and the vacuum chamber are reduced, and/or wherein the sample stage cable at least partly has a shield in the section guided in the vacuum chamber, such that electrostatic discharges between the sample stage cable and the vacuum chamber are reduced.

The charged particles can be e.g. electrons, positrons, muons or ions or other charged particles. Optionally, the charged particles are electrons generated e.g. using a thermal field emission source (TFE). However, other particle sources can also be used.

The individual particle beams can be arranged in a grid arrangement, that is to say an arrangement of the individual particle beams relative to one another can be fixed or can be selected. Optionally, this is a regular grid arrangement, which can provide, for example, a square, rectangular or hexagonal arrangement of the individual particle beams relative to one another, for example with uniform spacing. It can be desirable if the number of individual particle beams is 3 n (n−1)+1, where n is any natural number.

The multi-beam particle microscope can be a system operating with a single column, but it is also possible for the multi-beam particle microscope to be realized via a multi-column system. Optionally, the multi-beam particle microscope comprises only one objective lens (which can in turn be multipartite), through which all of the individual particle beams pass. However, it is also possible for a plurality of objective lenses to be provided or for an objective lens array to be provided, wherein only a first individual particle beam or only a subgroup of all the individual particle beams passes through each objective lens (which can in turn be multipartite) of the objective lens array. Accordingly, it is possible for only one objective lens cable to be provided in order to apply a high voltage to the objective lens. However, it is also possible for a plurality of objective lens cables to be provided in order to apply a high voltage to one or a plurality of objective lenses. The fewer objective lens cables involved, the better this is for reducing the undesired particle beam-induced traces on the sample. Optionally, therefore, only one objective lens cable is provided.

The sample stage serves for holding and/or positioning a sample during the inspection. As a result of a high voltage being applied to the sample stage, a sample that is arrangeable or arranged thereon is also at the same potential. For this purpose, optionally only a single sample stage cable is used, but it is also possible to provide a plurality of sample stage cables.

Hereinafter, reference is always made to an objective lens cable and a sample stage cable in the singular; however, it is also possible, of course, that a plurality of cables having the properties described below are provided in each case.

The objective lens cable and the sample stage cable can be guided at least sectionally in the vacuum chamber. Therefore, the internal discharge or corona discharge described above could occur in these sections, if correspondingly high electric fields were present. Accordingly, a shield can be provided at least partly in the sections, the shield preventing the discharge. At least partly means two different things here: firstly, the shield need not (but can) be provided along the entire section that extends within the vacuum chamber and, secondly, the shield of the cable need not (but can) directly or indirectly 100% completely enclose or envelop or cover the surface of the cable at every point thereof.

In this case, the shield itself can be a shield which is known per se and which can be realized in various ways. The way in which the shield is realized can be identical for the objective lens cable and for the sample stage cable, but it can also be different. To be considered are the electrical conductivity of the shield and the sufficiently good confinement of the electric field according to the principle of the Faraday cage via the shield.

In accordance with one preferred embodiment of the disclosure, a length of the shield of the objective lens cable is at least 20 cm, and/or a length of the shield of the sample stage cable is at least 40 cm. Therefore, the shield is in each case effective throughout at least this length; that also applies to the cases in which the shield is provided in a manner not covering the cable 100%.

In accordance with one preferred embodiment of the disclosure, the vacuum that is generable or generated in the vacuum chamber is 10⁻⁷ mbar or better (and the pressure is thus lower). Optionally, the total pressure in the vacuum chamber is ≤10⁻⁸ mbar, such as approximately 10⁻⁹ mbar. These values relate to a situation in which high voltage is present at the objective lens and at the sample stage. The effect of the shield of the objective lens cable and the sample stage cable is very great even in the case of the already inherently very low total pressures mentioned above. That is noteworthy. Pressures of specific elements (more precisely: partial pressures) in the vacuum chamber can be reduced approximately by a factor of 10 by the cable shield on the objective lens cable and the sample stage cable.

Additionally or alternatively, the absolute value of a voltage that is able to be applied or is applied to the objective lens and/or to the sample stage is at least 15 kV, such as at least 20 kV, for example at least 30 kV. In the case of these high voltages or voltage differences in relation to the vacuum chamber (earth potential), the discharges described arise even in high vacuum. The objective lens is generally situated very closely upstream of the sample or the sample stage, such that optionally almost the same potential is present at the objective lens and the sample, for example in each case approximately ±20 kV, ±22 kV, ±25 kV, ±28 kV, ±30 k V or ±32 kV.

In accordance with one preferred embodiment of the disclosure, the objective lens cable and/or the sample stage cable comprise(s) an insulation around a core of the respective cable. In this case, the cable can be a single-core cable, but it can also be a multi-core cable. In this case, the shield is arranged respectively on the outside in relation to the insulation. As is known, the objective lens cable and the sample stage cable already typically can have an insulation whose material has only a low level of outgassing. It should therefore be noted at this juncture that theoretically omitting the insulation would solve the issue of outgassing, but not the issue addressed by the disclosure pertaining to the internal discharge or corona discharge in the residual gas and the associated arising and accelerating of ions of the residual gas, which in turn leads to increased detachment or ejection of particles in the region of the cables or the walls of the vacuum chamber. Therefore, the already known insulations can also be maintained in combination with the shield according to the disclosure.

In accordance with one preferred embodiment of the disclosure, the insulation comprises a plastic, which is hydrophobic, which has a low level of outgassing and/or which is elastic. The elasticity enables the flexibility of the cable together with its insulation. The outgassing rates for plastics are often specified as TML (“Total Mass Loss”) or CVCM (“Collected Volatile Condensable Material”). The total mass loss is the percentage of the mass which is lost after the sample has been heated to 125° C. for 24 hours under vacuum. The CVCM is that proportion of the mass which condenses on a nearby test surface at 25° C. TML and CVCM can be used to compare different materials with regard to their suitability for use in vacuum. In order to predict the actual pressure which would be attained in a system, or in order to calculate the suction capacity for attaining a desired pressure, an outgassing rate can be specified, expressed as (volume multiplied by pressure) per unit area per unit time. A low level of outgassing within the meaning of this patent application is present if at least one of the following relations is satisfied: TML≤1%, CVMC≤0.02, outgassing rate≤10⁻⁷ torr*litre/cm²*s).

In accordance with one preferred embodiment of the disclosure, the plastic is selected from at least one of the following groups of plastics: polyimides, polyethylenes, polypropylenes, polytetrafluoroethylenes, fluorinated ethylene propylenes, perfluoroalkoxyalkanes.

In accordance with one preferred embodiment of the disclosure, the shield of the objective lens cable and/or of the sample stage cable is electrically conductive and free of organic material and for example also free of fluoro-organic material. Consequently, owing to their conductivity, metals and/or semi-metals and alloys thereof are suitable, in principle, as shield. Metals used can include copper, aluminium and/or silver, but other metals can also be used. Dispensing with organic and for example fluoro-organic material can be desirable since carbon can be adsorbed particularly effectively and thus disruptively on a sample surface or deposits there in a particle beam-induced fashion.

In accordance with one preferred embodiment of the disclosure, the shield comprises a braided shield. By way of example, the shield is braided from bare or tin-plated copper wires, wherein the tin-plated embodiment has significantly better properties against corrosion. A braided shield can exhibit very good damping and good mechanical properties. Highly flexible lines can be produced with approximately 70% linear and 90% optical coverage with a specific braiding angle, which avoids tensile forces on the shielding wires. However, other embodiment variants are also possible.

Additionally or alternatively, it is also possible for the shield to comprise a twisted shield. A coverage of the internal conductor generally ranges between 95% and 100%.

By way of example, a shield composed of bare or tin-plated copper wires is laid over or wound around the internal conductor(s), wherein the tin-plated embodiment has significantly better properties against corrosion. A twisted shield can involve simple, fast and inexpensive production. As an alternative to copper, other metals can also be used, for example aluminium or silver.

Additionally or alternatively, it is also possible for the shield to comprise a foil, such as an aluminium foil. It is possible for a foil to be coated with aluminum. Optionally, a foil affords 100% coverage, but it can also have cutouts or holes, without its function being appreciably impaired.

In accordance with one preferred embodiment of the disclosure, the shield is applied to the cable, and for example to the insulation of the cable, by vapour deposition (for example electron beam evaporation, resistance evaporation or generally physical vapour deposition (PVD)). Optionally, a coverage is complete or 100%. For a thickness Sd of the layer produced by vapour deposition, it can hold true that 10 nm≤Sd≤200 nm, for example 10 nm, 20 nm, 30 nm, 50 nm, 80 nm, 100 nm, 150 nm or 200 nm. In this case, a good adhesion of the applied substances on the cable or the insulator is relevant and, of course, dependent on the material combination respectively used, as is familiar to a person skilled in the relevant art.

In accordance with one preferred embodiment of the disclosure, the shield applied by vapour deposition comprises at least one metal from the group of metals listed below: platinum, palladium, copper, titanium, aluminum, gold, silver, chromium, tantalum, tungsten, molybdenum.

Additionally or alternatively, in accordance with a further preferred embodiment, the shield applied by vapour deposition comprises at least one semi-metal from the group of semi-metals listed below: Si, Si/Ge, GaAs, AlAs, InAs, GaP, InP, InSb, GaSb, GaN, AlN, InN, ZnSe, ZnS, CdTe.

The above-described embodiments of the disclosure can be combined with one another in full or in part, provided that no technical contradictions arise as a result.

Of course, it is also possible to shield one or more further cables analogously to the shields of the objective lens cable and of the sample stage cable.

### BRIEF DESCRIPTION OF THE DRAWINGS

The disclosure will be understood even better with reference to the accompanying figures, in which:

FIG. 1: shows a schematic illustration of a multi-beam particle microscope (MSEM);

FIG. 2: shows a schematic section through a multi-beam particle microscope;

FIG. 3: illustrates a measurement of partial pressures of residual gases in a high vacuum;

FIG. 4: schematically shows a vacuum chamber of a multi-beam particle microscope with objective lens cable and sample stage cable;

FIG. 5A: schematically illustrates the effect of the corona discharge in the vacuum chamber; and

FIG. 5B: schematically illustrates the prevention of the corona discharge in the vacuum chamber via a shield.

### DETAILED DESCRIPTION

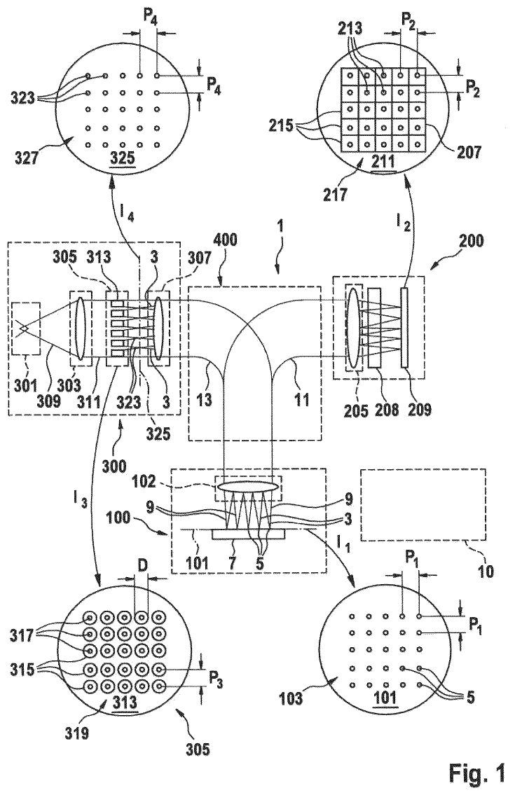

FIG. 1 is a schematic illustration of a particle beam system 1 in the form of a multi-beam particle microscope 1, which uses a plurality of particle beams. The particle beam system 1 produces a plurality of particle beams which are incident on an object to be examined in order to generate there interaction products, e.g. secondary electrons, which emanate from the object and are subsequently detected. The particle beam system 1 is of the scanning electron microscope (SEM) type, which uses a plurality of primary particle beams 3 which are incident on a surface of the object 7 at a plurality of locations 5 and produce there a plurality of electron beam spots, or spots, that are spatially separated from one another. The object 7 to be examined can be of any desired type, e.g. a semiconductor wafer or a biological sample, and can comprise an arrangement of miniaturized elements or the like. The surface of the object 7 is arranged in a first plane 101 (object plane) of an objective lens 102 of an objective lens system 100.

The enlarged detail I1 in FIG. 1 shows a plan view of the object plane 101 having a regular rectangular field 103 of incidence locations 5 formed in the first plane 101. In FIG. 1, the number of incidence locations is 25, which form a 5×5 field 103. The number 25 of incidence locations is a number chosen for reasons of simplified illustration. In practice, the number of beams, and hence the number of incidence locations, can be chosen to be significantly greater, such as, for example, 20×30, 100×100 and the like.

In the illustrated embodiment, the field 103 of incidence locations 5 is a substantially regular rectangular field having a constant spacing P1 between adjacent incidence locations. Exemplary values of the spacing P1 are 1 micrometre, 10 micrometres and 40 micrometres. However, it is also possible for the field 103 to have other symmetries, such as a hexagonal symmetry, for example.

A diameter of the beam spots shaped in the first plane 101 can be small. Exemplary values of the diameter are 1 nanometre, 5 nanometres, 10 nanometres, 100 nanometres and 200 nanometres. The focusing of the particle beams 3 for shaping the beam spots 5 is carried out by the objective lens system 100.

The primary particles incident on the object generate interaction products, e.g. secondary electrons, backscattered electrons or primary particles that have experienced a reversal of movement for other reasons, which emanate from the surface of the object 7 or from the first plane 101. The interaction products emanating from the surface of the object 7 are shaped by the objective lens 102 to form secondary particle beams 9. The particle beam system 1 provides a particle beam path 11 for guiding the plurality of secondary particle beams 9 to a detector system 200. The detector system 200 comprises a particle optical unit having a projection lens 205 for directing the secondary particle beams 9 onto a particle multi-detector 209.

The detail 12 in FIG. 1 shows a plan view of the plane 211, in which individual detection regions of the particle multi-detector 209 on which the secondary particle beams 9 are incident at locations 213 are located. The incidence locations 213 lie in a field 217 with a regular spacing P2 from one another. Exemplary values of the spacing P2 are 10 micrometres, 100 micrometres and 200 micrometres.

The primary particle beams 3 are generated in a beam generating apparatus 300 comprising at least one particle source 301 (e.g. an electron source), at least one collimation lens 303, a multi-aperture arrangement 305 and a field lens 307. The particle source 301 generates a diverging particle beam 309, which is collimated or at least substantially collimated by the collimation lens 303 in order to shape a beam 311 which illuminates the multi-aperture arrangement 305.

The detail 13 in FIG. 1 shows a plan view of the multi-aperture arrangement 305. The multi-aperture arrangement 305 comprises a multi-aperture plate 313, which has a plurality of openings or apertures 315 formed therein. Midpoints 317 of the openings 315 are arranged in a field 319 that is imaged onto the field 103 formed by the beam spots 5 in the object plane 101. A spacing P3 between the midpoints 317 of the apertures 315 can have exemplary values of 5 micrometres, 100 micrometres and 200 micrometres. The diameters D of the apertures 315 are smaller than the distance P3 between the midpoints of the apertures. Exemplary values of the diameters D are 0.2×P3, 0.4×P3 and 0.8×P3.

Particles of the illuminating particle beam 311 pass through the apertures 315 and form particle beams 3. Particles of the illuminating beam 311 which are incident on the plate 313 are absorbed by the latter and do not contribute to the formation of the particle beams 3.

On account of an applied electrostatic field, the multi-aperture arrangement 305 focuses each of the particle beams 3 in such a way that beam foci 323 are formed in a plane 325. Alternatively, the beam foci 323 can be virtual. A diameter of the beam foci 323 can be, for example, 10 nanometres, 100 nanometres and 1 micrometre.

The field lens 307 and the objective lens 102 provide a first imaging particle optical unit for imaging the plane 325, in which the beam foci 323 are formed, onto the first plane 101 such that a field 103 of incidence locations 5 or beam spots arises there. If a surface of the object 7 is arranged in the first plane, the beam spots are correspondingly formed on the object surface.

The objective lens 102 and the projection lens arrangement 205 provide a second imaging particle optical unit for imaging the first plane 101 onto the detection plane 211. The objective lens 102 is thus a lens that is part of both the first and the second particle optical unit, while the field lens 307 belongs only to the first particle optical unit and the projection lens 205 belongs only to the second particle optical unit.

A beam switch 400 is arranged in the beam path of the first particle optical unit between the multi-aperture arrangement 305 and the objective lens system 100. The beam switch 400 is also part of the second particle optical unit in the beam path between the objective lens system 100 and the detector system 200.

Further information relating to such multi-beam particle beam systems and components used therein, such as, for instance, particle sources, multi-aperture plate and lenses, can be obtained from the international patent applications WO 2005/024881 A2, WO2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which in the full scope thereof is incorporated by reference in the present application.

The multiple particle beam system 1 furthermore comprises a computer system 10 configured both for controlling the individual particle optical components of the multiple particle beam system and for evaluating and analysing the signals obtained by the multi-detector 209. The computer system 10 can be constructed from a plurality of individual computers or components. The multi-beam particle beam system in the form of a multi-beam particle microscope 1 can comprise the cable shield according to the disclosure on the objective lens cable and the sample stage cable.

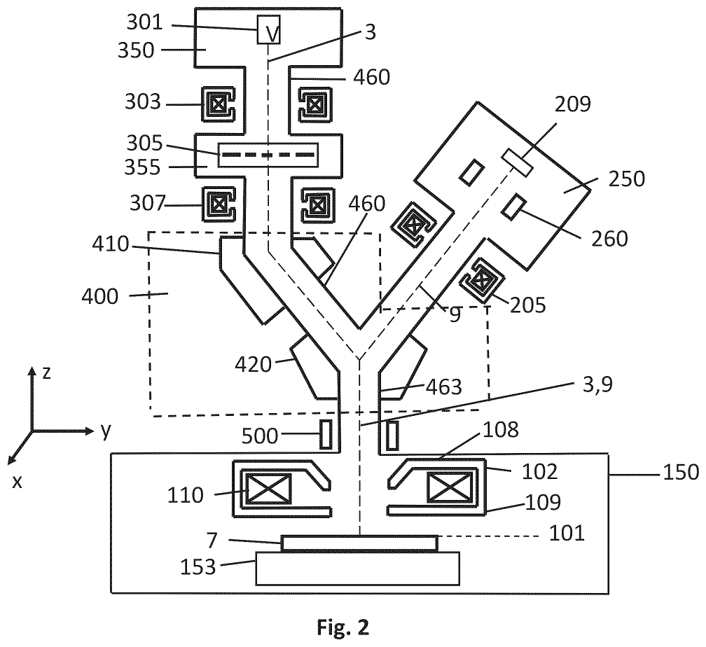

FIG. 2 schematically shows a sectional view of a multiple particle beam system such as, for example, the multi-beam particle microscope illustrated in FIG. 1. In this case, FIG. 2 primarily illustrates by way of example the particle optical beam path under vacuum. The multi-beam particle microscope 1 in accordance with the example shown in FIG. 2 once again firstly comprises a particle source 301. In the example shown, this particle source 301 emits an individual particle beam comprising charged particles, e.g. electrons. In this case, the particle source 301 can be operated with high voltage, for example with a voltage of at least ±20 kV or ±30 kV. In FIG. 2, particle beams or a particle optical beam path are illustrated schematically by the dashed line with reference sign 3. The individual particle beam 3 initially passes through a condenser lens system 303 and is subsequently incident on a multi-aperture arrangement 305. This multi-aperture arrangement 305, possibly with further particle optical components, serves as a multi-beam generator. The latter can be approximately at ground potential. The first particle beams emanating from the multi-aperture arrangement 305 then pass through a field lens or a field lens system 307 and subsequently enter a beam switch 400. After passing through the beam switch 400, the first particle beams pass through a scan deflector 500 and, thereupon, a particle optical objective lens 102, before the first particle beams 3 are incident on an object 7. As a result of this incidence, secondary particles, e.g. secondary electrons, are released from the object 7. These secondary particles form second particle beams, to which a second particle optical beam path 9 is assigned. After emerging from the object 7, the second particle beams initially pass through the particle optical objective lens 102 and subsequently pass through the scan deflectors 500, before the second particle beams enter the beam switch 400. Subsequently, the second particle beams 9 emerge from the beam switch 400, pass through a projection lens system 205, pass through an electrostatic element 260 and then impinge on a particle optical detector unit 209.

The particle beams 3, 9 move through a beam tube 460, which is evacuated. In some regions, the beam tube 460 widens to form larger chambers or is interrupted by the chambers. These include for example the chamber 350 in the region of the particle source 301, the chamber 355 in the region of the multi-aperture arrangement 305 of particle optical components such as, for example, the multi-beam generator or the multi-aperture arrangement 305, the chamber 250 in the region of the detection system 209 and also the vacuum chamber 150 in the region of the objective lens 102 and the sample stage 153 with a sample 7. In this case, a high vacuum optionally with a pressure of less than 10⁻⁵ mbar, such as less than 10⁻⁷ mbar and/or 10⁻⁹ mbar, prevails in the interior of the beam tube 460 within the beam switch 400. A vacuum optionally in each case with pressures of less than 10⁻⁵ mbar, such as less than 10⁻⁷ mbar and/or 10⁻⁹ mbar, prevails in the chambers 350, 355 and 250 already mentioned. A vacuum with total pressures of less than 10⁻⁷ mbar, such as less than 10⁻⁸ mbar and/or 10⁻⁹ mbar, can prevail in the vacuum chamber 150 encompassing the objective lens 102 and the sample stage 153 with the sample 7.

The objective lens 102 has an upper pole shoe 108 and a lower pole shoe 109. A winding 110 for generating a magnetic field is situated between the two pole shoes 108 and 109. In this case, the upper pole shoe 108 and the lower pole shoe 109 can be electrically insulated from one another. In the example shown, the particle optical objective lens 102 is a magnetic lens; however, it can also be an electrostatic lens or a combined magnetic/electrostatic lens. In this case, in the example shown, the objective lens is operated with high voltage, i.e. with a voltage which, in terms of absolute value, is at least 20 kV, such as at least 30 kV. It can be for example approximately ±20 kV, ±22 kV, ±25 kV, ±28 kV, ±30 kV or ±32 kV. The objective lens 102 and the sample stage 153 or the sample 7 are very close together, for which reason the voltage present at the sample stage 153 or at the sample 7 is also a high voltage of the same order of magnitude as at the objective lens 102. An objective lens cable 151 and a sample stage cable 152 are respectively used for applying the voltage (neither of which is illustrated in FIG. 2 for reasons of simplicity).

By virtue of the high voltage used, the multi-beam particle microscope 1 illustrated already differs from many other particle microscopes from known microscopes, in which a sample 7 is at ground potential. However, the fact that this difference is relevant to particle beam-induced or electron beam-induced traces on the sample 7 despite high vacuum in the region of the sample 7 became apparent only during detailed investigations by the applicant:

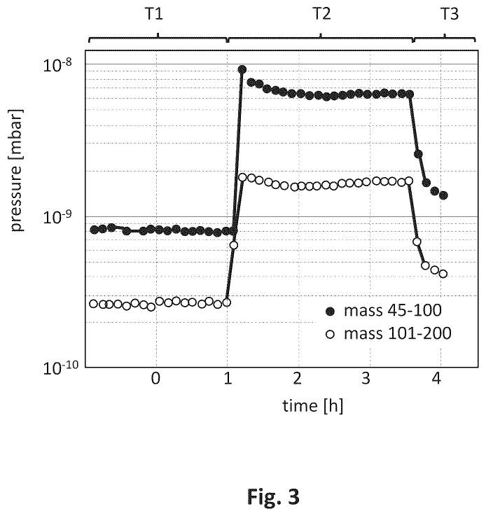

FIG. 3 illustrates measurements of partial pressures of residual gases in a high vacuum. Specifically, the applicant investigated the partial pressure of various elements or various residual gases in the vacuum chamber 150. A mass spectrometer was used to determine the partial pressures. Two curves are plotted in the illustration shown in FIG. 3; in one curve, illustrated by dots not filled in, the partial pressure of substances having the atomic masses 101 to 200 is plotted; the curve with the filled-in circles illustrates the partial pressure of substances having the atomic masses 45 to 100. In this case, the respective partial pressures are plotted against time.

The measurement of the partial pressures was begun in each case field-free, i.e. both the vacuum chamber 150 and the objective lens 102 and the sample stage 153 were grounded during the time interval T1 or no voltage was present there (that is to say that no imaging occurred during this time interval T1 with the multi-beam particle microscope—otherwise a voltage or high voltage would have had to have been applied to or have been present at the objective lens 102 and the sample stage 153. No imaging occurred during the time intervals T2 and T3 either). The respective partial pressures were approximately constant in the time interval T1 and were approximately 2×10⁻¹⁰ mbar and approximately 8×10⁻¹⁰ mbar, respectively. After one hour, a high voltage, approximately −30 kV in the example illustrated, was applied both to the objective lens cable 151 and to the sample stage cable 152. An abrupt rise in the respective partial pressures in each case by approximately one order of magnitude was observed directly after the high voltage had been applied. During the time interval T2 with high voltage applied, the partial pressures then once again remained approximately constant in each case. In the time interval T3, the high voltage was then switched off again, or that is to say that the two cables 151, 152 were grounded. The partial pressures thereupon recovered again or decreased slowly. The recovery did not occur abruptly, but rather gradually. What can firstly be deduced from this is that the occurrence of residual gas is voltage-induced or attributable to corona discharges between the cables 151, 152, on the one hand, and the grounded wall 159 of the vacuum chamber 150, on the other hand. A disturbance of the mass spectrometer owing to the high voltage carried by the cables can be ruled out since the decrease in the partial pressure after the high voltage had been switched off occurred gradually rather than abruptly. In this case, the residual gas measured when the high voltage was present during the time interval T2 arises as a result of the sputtering effect described above. If a discharge arises in the vacuum chamber 150, residual gas still present in the vacuum chamber 150 is ionized and the ions are accelerated according to their charge. They then strike the grounded wall 159 of the vacuum chamber 150, for example, or they impinge on the cables 151, 152, where they eject material such as from an insulator 158 surrounding the cables 151, 152, which material then moves freely in the vacuum chamber 150 and contributes to the residual gas there.

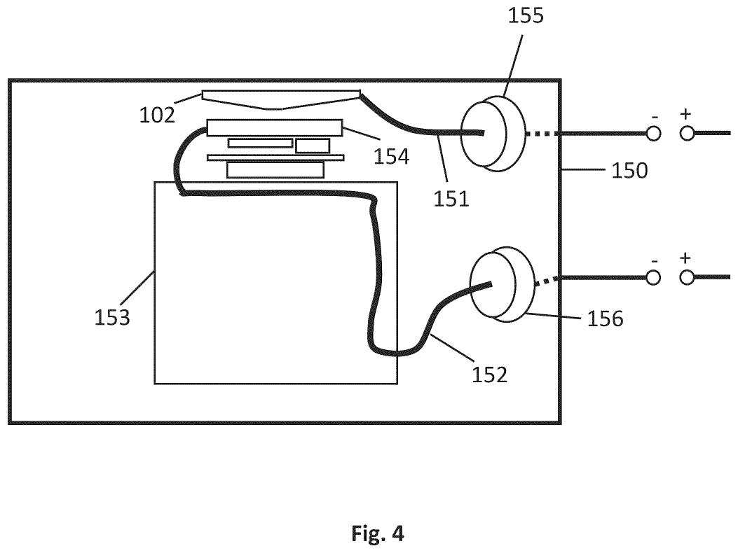

FIG. 4 schematically shows a vacuum chamber 150 of a multi-beam particle microscope 1 with objective lens cable 151 and sample stage cable 152. The sample stage 153 serves for holding and/or positioning a sample 7 during a sample inspection. The structure of the sample stage 153 is merely illustrated schematically overall; the example shown is concerned with a sample stage 153 which is adjustable in the z-direction or height-adjustable. The cable 152 is connected to the sample stage surface 154 of the sample stage, a high voltage being able to be applied or being applied to the cable. The objective lens 102 is situated just above the sample stage surface 154 and is merely illustrated highly schematically in FIG. 4. The objective lens cable 151 is connected to the objective lens 102. In the example shown, both cables 151, 152 are insulated or surrounded by an insulator 158. The latter can involve a polyimide, for example, which has a low level of outgassing and is elastic owing to the desired flexibility of the cables 151, 152. However, other materials are also possible. In the example shown, both cables 151, 152 are shielded over the entire length over which the two cables 151, 152 extend within the vacuum chamber 150. They are each guided into the chamber 150 by way of vacuum-suitable and high voltage-suitable connectors 155 and 156, respectively. The length of the objective lens cable or of the shielded section of the objective lens cable 151 within the vacuum chamber 150 is at least 20 cm in the example shown. The length of the shield of the sample stage cable 152 is at least 40 cm in the example shown. The specific length of the respective cables 151, 152 is also dependent, of course, on the design of the vacuum chamber 150.

In the example shown, the vacuum that is generable or generated in the vacuum chamber 150 is 10⁻⁷ mbar or better, where this specification relates to the total pressure of the residual gas. The absolute value of a voltage that is able to be applied or is applied to the objective lens 102 and/or to the sample stage 153 or the surface 154 thereof is at least 20 kV, for example at least 30 kV. The voltage is approximately-30 kV in the example shown, since electrons are used as charged particle beams in the example illustrated.

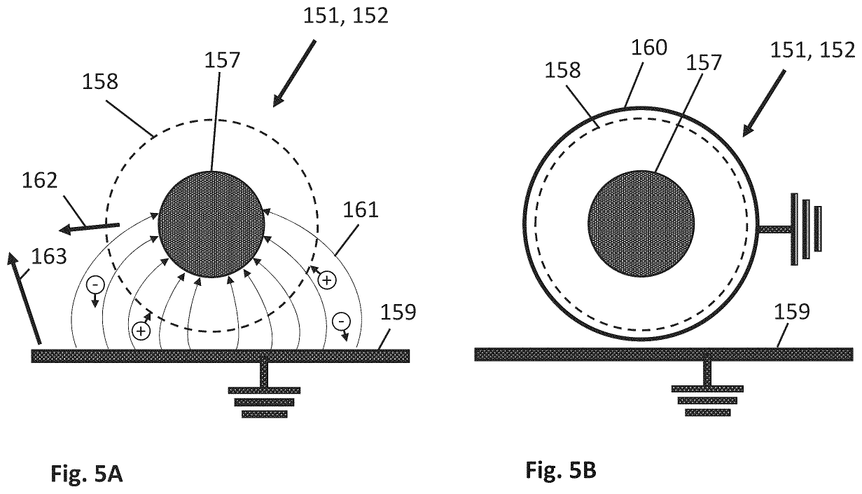

FIG. 5 schematically illustrates A) the effect of the corona discharge in the vacuum chamber 150 and B) the prevention of the corona discharge in the vacuum chamber 150 via a shield according to the disclosure.

In this case, the corona discharge in accordance with FIG. 5A) arises as follows: the cable 151, 152 comprises a conductive core 157 and an insulator 158 arranged around the latter. This can involve an insulation composed of plastic, which is hydrophobic, which has a low level of outgassing and/or which is elastic. In this case, the plastic can be selected from at least one of the following groups of plastics: polyimides, polyethylenes, polypropylenes, polytetrafluoroethylenes, fluorinated ethylene propylenes, perfluoroalkoxyalkanes. However, other plastics can also be used.

The cable 151, 152 then extends at least partly in proximity to the wall 159 of the vacuum chamber 150, which is grounded. Strong electric fields arise between the core 157 of the cable 151, 152 and the wall 159, the field lines of the electric fields being indicated by the lines or arrows 161 in FIG. 5A). A corona discharge then arises on account of the high electric field strength between the core 157 and the wall 159, in the course of which corona discharge the residual gas present in the vacuum chamber 150 is ionized. Positively charged and negatively charged ions are therefore illustrated schematically in FIG. 5A). In the example shown, the negatively charged ions move at high speed towards the wall 159 and, upon striking the wall 159, eject particles from the wall 159. This is indicated by the arrow 163. The ejected particles form an additional residual gas, which can be detected or measured in the vacuum chamber 150. Conversely, in the example shown (potential of the core 157 at −30 kV, for example), the positively charged ions move at high speed towards the insulator 158 and, upon striking the latter, eject material from the insulator 158, which is indicated by the arrow 162. These particles, too, then form additional residual gas in the vacuum chamber 150.

FIG. 5B) then shows the situation when a shield 160 according to the disclosure is present: the shield 160 confines the electric field of the conductive core 157 of the cable 151, 152 within the shield. There is no longer any potential difference between the shield 160, which is at ground potential, and the wall 159 of the vacuum chamber 150. In this way, a corona discharge is avoided, nor is there additional residual gas formation in the vacuum chamber 150. Consequently, particle beam-induced or electron beam-induced trace formation on a sample surface can also be reduced.

The shield 160 of the objective lens cable 151 and/or of the sample stage cable 152 is electrically conductive and, in the example shown, free of organic material and for example also free of fluoro-organic material. In this case, the shield itself can be realized in various ways; it can be realized identically or differently for the objective lens cable 151 and the sample stage cable 152. In accordance with one example, the shield 160 comprises a braided shield. In this case, the shield can be braided from bare or tin-plated copper wires, wherein the tin-plated embodiment has significantly better properties against corrosion. A braided shield has very good damping and good mechanical properties. Highly flexible lines can be produced with approximately 70% linear and 90% optical coverage with a specific braiding angle, which avoids tensile forces on the shielding wires of the shield 160. However, other embodiment variants are also possible.

Additionally or alternatively, it is also possible for the shield 160 to comprise a twisted shield. A coverage of the internal conductor or of the cable comprising the core 157 and the insulator 158 generally can range between 95% and 100%. In the case of the twisted shield described, a shield composed of bare or tin-plated copper wires or wires composed of some other material, for example aluminum or silver, is laid over or wound around the cable.

Additionally or alternatively, it is also possible for the shield 160 to comprise a foil, such as an aluminium foil. It is also possible for a foil to be coated with aluminum. Optionally, a foil then affords 100% coverage, but it can also have cutouts and/or holes, without its function being appreciably impaired.

In accordance with one preferred embodiment of the disclosure, the shield 160 is applied to the objective lens cable 151 and/or the sample stage cable 152, and for example to the respective insulations of the cables 151, 152, by vapour deposition. For this purpose, electron beam evaporation or resistance evaporation can be used, for example, but generally physical vapour deposition (PVD) is also possible. Optionally, a coverage via vapour deposition is complete or is 100%. A typical layer thickness Sd as a result of vapour deposition is 10 nm≤Sd≤200 nm, for example 10 nm, 20 nm, 30 nm, 50 nm, 80 nm, 100 nm, 150 nm or 200 nm. In this case, a good adhesion of the applied materials by way of vapour deposition on the cable 151, 152 or on an insulator 158 as the outermost layer of the cable 151, 152 is relevant and, of course, dependent on the material combination respectively used, as is familiar to a person skilled in the relevant art. By way of example, the shield 160 applied by vapour deposition can comprise at least one metal from the group of metals listed below: platinum, palladium, copper, titanium, aluminum, gold, silver, chromium, tantalum, tungsten, molybdenum. Additionally or alternatively, the shield 160 applied by vapour deposition can comprise at least one semi-metal from the group of semi-metals listed below: Si, Si/Ge, GaAs, AlAs, InAs, GaP, InP, InSb, GaSb, GaN, AlN, InN, ZnSe, ZnS, CdTe.

With the present disclosure, it has become possible to further reduce particle beam-induced traces on a sample 7 and thus to enable even better recordings via a multi-beam particle microscope 1.

### LIST OF REFERENCE SIGNS

1 Multi-beam particle microscope
3 Primary particle beams (individual particle beams)
5 Beam spots, incidence locations
7 Object
9 Secondary particle beams (individual particle beams)
10 Computer system, controller
11 Secondary particle beam path
13 Primary particle beam path
25 Sample surface, wafer surface
100 Objective lens system
101 Object plane
102 Objective lens
103 Field
108 Upper pole shoe
109 Lower pole shoe
150 Vacuum chamber
151 Objective lens cable
152 Sample stage cable
153 Sample stage, stage
154 Sample stage surface, stage surface
155 High-vacuum bushing
156 High-vacuum bushing
157 Core of the cable
158 Insulator
159 Vacuum chamber wall
160 Shield
161 Field lines
162 Arrow for illustrating the sputtering effect
163 Arrow for illustrating the sputtering effect
200 Detector system
205 Projection lens
209 Particle multi-detector
211 Detection plane
213 Incidence locations
215 Detection region
217 Field
250 Vacuum chamber
300 Beam generating apparatus
301 Particle source
303 Collimation lens system
305 Multi-aperture arrangement, multi-beam generator
306 Micro-optics
307 Field lens
309 Diverging particle beam
311 Illuminating particle beam
313 Multi-aperture plate
315 Openings in the multi-aperture plate
317 Midpoints of the openings
319 Field
323 Beam foci
325 Intermediate image plane
350 Vacuum chamber
355 Vacuum chamber
400 Beam switch
410 Magnetic sector
420 Magnetic sector
460 Beam tube arrangement
500 Scan deflector

What is claimed is:

1. A multi-beam particle microscope, comprising:
a vacuum chamber;
a multi-beam generator configured to produce a first field of a plurality of charged first individual particle beams;
a first particle optical unit with a first particle optical beam path, the first particle optical unit configured to image the produced individual particle beams onto a sample surface in an object plane so that the first individual particle beams are incident on the sample surface at incidence locations, which define a second field;
a detection system comprising a plurality of detection regions that define a third field;
a second particle optical unit with a second particle optical beam path, the second particle optical unit configured to image second individual particle beams, which emanate from the incidence locations in the second field, onto the third field of the detection regions of the detection system;
an objective lens configured to have the first and the second individual particle beams pass therethrough;
a beam switch in the first particle optical beam path between the multi-beam generator and the objective lens, the beam switch being in the second particle optical beam path between the objective lens and the detection system;
a sample stage configured to hold and/or position a sample during a sample inspection;
a high voltage cable;
an objective lens cable guided at least sectionally within the vacuum chamber;
a sample stage cable guided at least sectionally within the vacuum chamber;
a shield; and
a controller configured to control the multi-beam particle microscope,
wherein:
the objective lens comprises a magnetic objective lens and/or an electrostatic objective lens;
the vacuum chamber is grounded;
the objective lens and the sample stage are in the vacuum chamber;
the objective lens is configured to have a high voltage applied thereto via the objective lens cable;
the sample stage is configured to have a high voltage applied thereto via the sample stage cable; and
the shield is configured to reduce electrostatic discharges between the objective lens cable and the vacuum chamber, or the shield is configured to reduce electrostatic discharges between the sample stage cable and the vacuum chamber.

2. The multi-beam particle microscope of claim 1, wherein the shield is configured to shield an entire region of the objective lens cable in the vacuum chamber.

3. The multi-beam particle microscope of claim 2, further comprising a second shield which is configured to shield an entire section of the sample stage cable in the vacuum chamber.

4. The multi-beam particle microscope of claim 1, wherein the shield is configured to shield an entire section of the sample stage cable in the vacuum chamber.

5. The multi-beam particle microscope of claim 1, wherein the shield is at least 20 centimeters long, and/or the shield of the sample stage cable is at least 40 centimeters.

6. The multi-beam particle microscope of claim 1, wherein the vacuum chamber is configured to have a vacuum of 10⁻⁷ millbar or less, and/or an absolute value of a voltage that is able to be applied or is applied to the objective lens and/or to the sample stage is at least 15 kV.

7. The multi-beam particle microscope of claim 1, wherein the objective lens cable and/or the sample stage cable comprises an insulation around a core of the cable, and the shield is disposed outside the insulation.

8. The multi-beam particle microscope of claim 7, wherein the insulation comprises a plastic.

9. The multi-beam particle microscope of claim 7, wherein the insulation comprises at least one material selected from the group consisting of polyimides, polyethylenes, polypropylenes, polytetrafluoroethylenes, fluorinated ethylene propylenes, and perfluoroalkoxyalkanes.

10. The multi-beam particle microscope of claim 1, wherein the shield is electrically conductive and free of organic material.

11. The multi-beam particle microscope of claim 1, wherein the shield comprises a braided shield.

12. The multi-beam particle microscope of claim 1, wherein the shield comprises a twisted shield.

13. The multi-beam particle microscope of claim 1, wherein the shield comprises a foil.

14. The multi-beam particle microscope of claim 1, wherein the shield is disposed on the objective lens cable or the sample stage cable.

15. The multi-beam particle microscope of claim 14, wherein the shield comprises at least one metal selected from the group consisting of platinum, palladium, copper, titanium, aluminum, gold, silver, chromium, tantalum, tungsten, and molybdenum.

16. The multi-beam particle microscope of claim 14, wherein the shield comprises at least one material selected from the group consisting of Si, Si/Ge, GaAs, AlAs, InAs, GaP, InP, InSb, GaSb, GaN, AlN, InN, ZnSe, ZnS, and CdTe.

17. The multi-beam microscope of claim 14, wherein the shield is configured to reduce electrostatic discharges between the objective lens cable and the vacuum chamber.

18. The multi-beam microscope of claim 1, wherein the shield is configured to reduce electrostatic discharges between the sample stage cable and the vacuum chamber.

19. The multi-beam microscope of claim 1, comprising first and second shields, wherein the first shield is configured to reduce electrostatic discharges between the sample stage cable and the vacuum chamber, and the second shield is configured to reduce electrostatic discharges between the objective lens cable and the vacuum chamber.

20. A multi-beam particle microscope, comprising:
a vacuum chamber;
a multi-beam generator configured to produce a first field of a plurality of charged first individual particle beams;
a first particle optical unit with a first particle optical beam path, the first particle optical unit configured to image the produced individual particle beams onto a sample surface in an object plane so that the first individual particle beams are incident on the sample surface at incidence locations, which define a second field;
a detection system comprising a plurality of detection regions that define a third field;
a second particle optical unit with a second particle optical beam path, the second particle optical unit configured to image second individual particle beams, which emanate from the incidence locations in the second field, onto the third field of the detection regions of the detection system;
an objective lens configured to have the first and the second individual particle beams pass therethrough;
a beam switch in the first particle optical beam path between the multi-beam generator and the objective lens, the beam switch being in the second particle optical beam path between the objective lens and the detection system;
a sample stage configured to hold and/or position a sample during a sample inspection;
a high voltage cable;
an objective lens cable guided at least sectionally within the vacuum chamber;
a first insulation supported by the objective lens cable;
a sample stage cable guided at least sectionally within the vacuum chamber;
a second insulation supported by the sample stage lens cable;
a first shield;
a second shield; and
a controller configured to control the multi-beam particle microscope,
wherein:
the objective lens comprises a magnetic objective lens and/or an electrostatic objective lens;
the vacuum chamber is grounded;
the objective lens and the sample stage are in the vacuum chamber;
the objective lens is configured to have a high voltage applied thereto via the objective lens cable;
the sample stage is configured to have a high voltage applied thereto via the sample stage cable;
the first shield is configured to reduce electrostatic discharges between the objective lens cable and the vacuum chamber; and
the second shield is configured to reduce electrostatic discharges between the sample stage cable and the vacuum chamber.
